(19) United States
(12) Patent Application Publication
(10) Pub. No.: US 2026/0239661 A1
(43) Pub. Date: Aug. 13, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: HSIN-CHIH CHIANG, HSINCHU CITY (TW); CHIH-CHANG CHENG, HSINCHU CITY (TW); MING-TA LEI, HSIN-CHU CITY (TW)

(21) Appl. No.: 19/050,171

(22) Filed: Feb. 11, 2025

(51) Int. Cl. H10D 30/65; H10D 30/01; H10D 62/10; H10D 64/00; H10D 64/27

(52) U.S. Cl. CPC H10D 30/655; H10D 30/0285; H10D 62/102; H10D 64/111; H10D 64/516; H10D 64/518

(57) ABSTRACT

A semiconductor structure is provided. The semiconductor structure includes a well structure, a spacing structure, a gate structure and a metal field plate. The well structure is formed on a semiconductor substrate and includes a first well region of a first conductivity type and a second well region of a second conductivity type opposite to the first conductivity type. The spacing structure is formed on the second well region and includes insulating materials. The gate structure is partially formed on the well region and partially formed on the spacing structure. The metal field plate is formed above the spacing structure and connects the gate structure. The metal field plate has a conductive material. A bottom of the spacing structure is substantially coplanar with a top of the first well region and a top of the second well region.

### BACKGROUND

High voltage metal-oxide-semiconductor (HV MOS) transistors, such as laterally diffused metal oxide semiconductor (LDMOS) transistors, are widely used in applications like automobile industry, display drivers, portable telecommunication devices and medical equipment. The LDMOS transistors are often utilized for high-voltage applications. It is desirable that LDMOS transistors possess a higher breakdown voltage and a lower on-resistance (RON).

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a cross sectional view of a semiconductor structure, in accordance with some embodiments of the present disclosure.

FIG. 2 illustrates a cross sectional view of a semiconductor structure including a metal field plate, in accordance with some embodiments of the present disclosure.

FIG. 3 illustrates a cross sectional view of a semiconductor structure including a metal field plate, in accordance with some another embodiments of the present disclosure.

FIG. 4 is a flowchart of a method for forming the semiconductor structure in accordance with some embodiments.

FIGS. 5 to 16 illustrate various perspective views of forming the semiconductor structure in accordance with some embodiments as described in FIG. 4.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Performance of a HV MOS transistor is often limited by its breakdown voltage (BV) threshold. A number of techniques developed to improve the breakdown voltage have typically increased the device's on-state resistance (Ron), which depends on the breakdown voltage BV of a HV MOS device in a relationship described as:

$$Ron = constant * B V 2.5 ( m Ω - {cm}^{2} )$$

A higher breakdown voltage BV induces a much higher (to the power of 2.5) resistance Ron, thus a much higher power consumption (P=I²Ron). For example, a 33% increase in breakdown voltage BV doubles the power loss.

Furthermore, various manufacturing processes currently have been developed to produce the MOS transistors. In some embodiments, the production of the MOS transistors includes forming an epitaxial layer on a semiconductor substrate, then forming shallow trench isolation (STI) in the epitaxial layer, and followed by forming a gate of the transistor by various steps in the corresponding trenches. In almost all existing gate processes to produce the MOS transistors, shortcomings of a high total gate charge (Qg) and a high practical figure of merit (FOM) are usually found. A higher total gate charge would reduce a switch speed of the MOS transistors, but will increase the gate loss, from which the switching loss would be raised but the performance will be reduced, respectively. The practical FOM is determined by the on-resistance and the total gate charge (Ron×Qg). A higher practical FOM tells that the conduction loss and the switch loss are worse. In some cases, the Ron×Qg performance would be limited due to the STI structure.

Therefore, there is a need to develop a semiconductor structure, which has a reduced Ron×Qg and a high breakdown voltage (BV) threshold, while maintains a low power consumption.

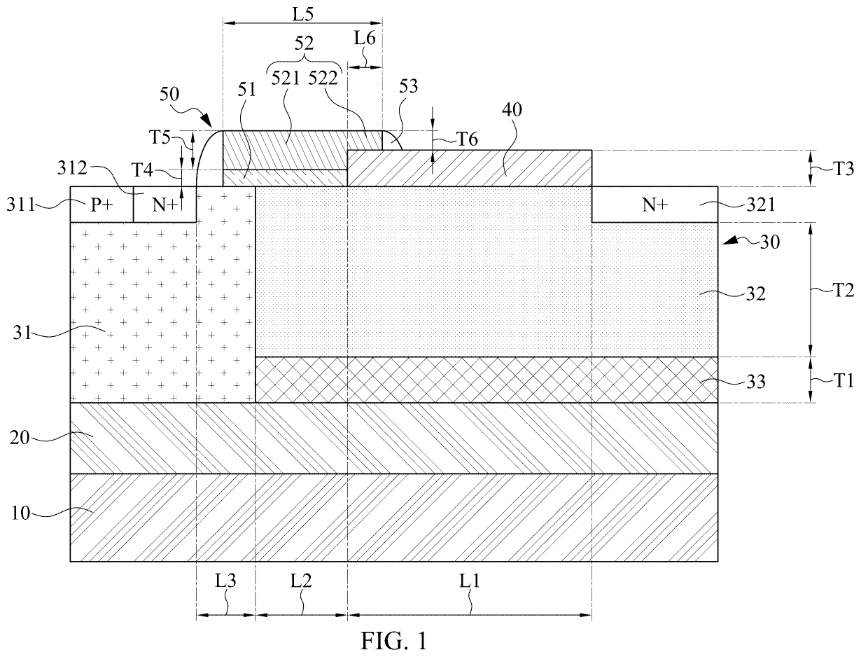

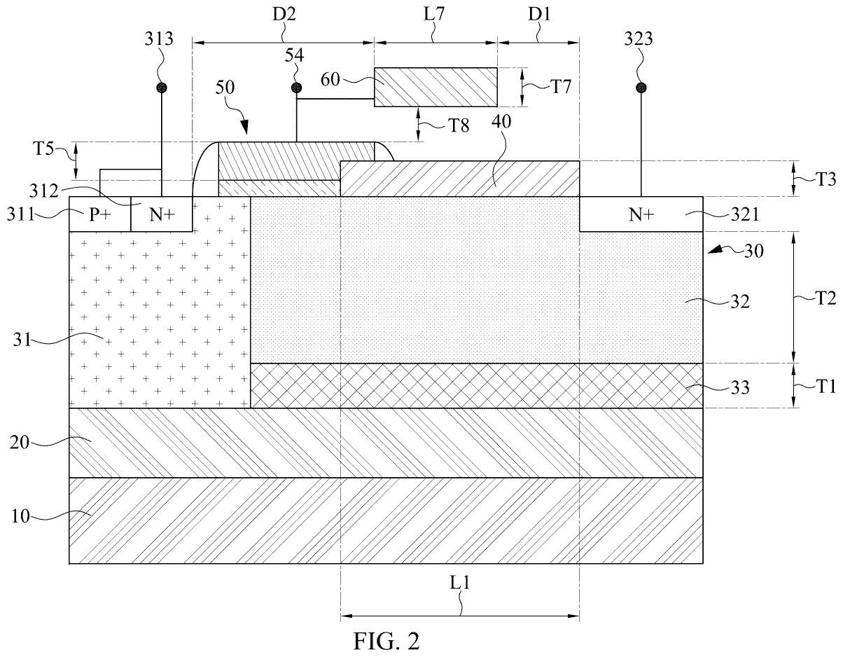

In some embodiments, a semiconductor structure is provided in accordance with aspects of the present disclosure. Referring to FIGS. 1 and 2, the semiconductor structure comprises a semiconductor substrate 10, a buried layer 20, a well structure 30, a spacing structure 40, a gate structure 50 and a metal field plate 60.

The semiconductor substrate 10 may include a semiconductor wafer, such as a silicon wafer. Alternatively, the semiconductor substrate 10 may include other elementary semiconductors, such as germanium. The semiconductor substrate 10 may also include a compound semiconductor, such as silicon carbide, gallium arsenic, indium arsenide, and indium phosphide. The semiconductor substrate 10 may include an alloy semiconductor, such as silicon germanium, silicon germanium carbide, gallium arsenic phosphide, and gallium indium phosphide. In some embodiments, the semiconductor substrate 10 includes an epitaxial layer (epi layer) overlaying a bulk semiconductor. Furthermore, the semiconductor substrate 10 may include a semiconductor-on-insulator (SOI) structure. For example, the semiconductor substrate 10 may include a buried oxide (BOX) layer formed by a process such as separation by implanted oxygen (SIMOX). The semiconductor substrate 10 may be of n-type or p-type. In some embodiment, the semiconductor structure of the present disclosure is fabricated on a p-type semiconductor substrate 10. The p-type semiconductor substrate 10 may have a resistivity ranging from about 1 ohm-cm to about 100 ohm-cm.

In various embodiments, the buried layer 20 is formed on the semiconductor substrate 10 and may be an n-type buried layer (NBL), a p-type buried layer (PBL), and/or a buried dielectric layer including a buried oxide (BOX) layer. In some embodiment, the buried layer 20 may comprise n-type dopants (e.g., N+ dopants) including phosphorus, arsenic, other n-type dopant, or combinations thereof to form an n-type buried layer (NBL) on a p-type semiconductor substrate 10.

The well structure 30 is formed on the buried layer 20 and may comprise a first well region 31 of a first conductivity type, a second well region 32 of a second conductivity type opposite to the first conductivity type. When the first conductivity type is n type, the second conductivity type is p type; and when the first conductivity type is p type, the second conductivity type is n type. Any suitable p-type dopant may be used, such as one or more of boron (B), gallium (Ga), or indium (In), etc.; any suitable N-type dopant may be used, such as one or more of phosphorous (P), arsenic (As), antimony (Sb), bismuth (Bi), lithium (Li), etc. In some embodiments, a p-type doping concentration may range from about 1E11 cm⁻² to about 9E13 cm⁻² and an n-type doping concentration may range from about 1E11 cm⁻² to about 9E13 cm⁻².

The first well region 31 may be a p type region and comprises a pair of oppositely doped regions 311 and 312, including a first doped region 311 comprising dopants of the first conductivity type and a second doped region 312 comprising dopants of the second conductivity type. In some embodiments, the first doped region 311 and the second doped region 132 are formed in a top region of the first well region 31, so that a top of the first doped region 311 and a top of the second doped region 312 are exposed. A source terminal 313 is electrically connected to the first doped region 311 and the second doped region 312 as shown in FIG. 2. The first doped region 311 may comprise highly doped p-type dopants (e.g., P+ dopants) including B, Ga, or In at a concentration from about 1E14 cm⁻² to about 1E16 cm⁻². The second doped region 312 may comprise highly doped n-type dopants (e.g., N+ dopants) including phosphorus, arsenic, other n-type dopant, or combinations thereof at a concentration from about 1E14 cm⁻² to about 1E16 cm⁻². The first well region 31 may have a resistivity ranging from about 1 ohm-cm to about 100 ohm-cm.

The second well region 32 may be an n-type region and comprises a drain area 321 formed in a top region of the second well region 32, so that a top of the drain area 321 is exposed. In some embodiments, the drain area 321 serves as a drain area. A drain terminal 323 is electrically connected to the drain area 321 as shown in FIG. 2. The drain area 321 may comprise highly doped n-type dopants (e.g., n+ dopants) including phosphorus, arsenic, other n-type dopant, or combinations thereof at a concentration from about 1E14 cm⁻² to about 1E16 cm⁻².

In some embodiments, a top of the first well region 31 may be substantially coplanar with a top of the second well region 32; and the top of the first doped region 311, the top of the second doped region 312 and the top of the drain area 321 may be substantially coplanar with each other.

In some embodiments, the well structure 30 may further comprise one or more additional well regions. As shown in FIGS. 1 and 2, a third well region 33 may be formed between the second well region 32 and the buried layer 20 and adjacent to the first well region 31. In some embodiments, a bottom of the first well region 31 may be coplanar with a bottom of the second well region 32. In some embodiments, a thickness T1 of the third well region 33 may be equal to or less than a thickness T2 of the second well region 32. In some embodiments, a ratio of the thickness T1 to the thickness T2 may range from about 1:20 to about 1:1. In some embodiments, a ratio of the thickness T1 to the thickness T2 may range from about 1:10 to about 1:1. In some embodiments, a ratio of the thickness T1 to the thickness T2 may range from about 1:5 to about 1:1. In some embodiments, the third well region 33 include dopants complementary to the dopants in the second well region 32. For example, when the second well region 32 is an n-type region, the third well region 33 may be p-type region. A p-type doping concentration of the third well region 33 may range from about 1E11 cm⁻² to about 9E13 cm⁻².

The spacing structure 40 is formed on the second well region 32 and may comprise insulating materials, such as oxide, including but not limited to silicon oxide, metal oxide or any other oxide materials. In some embodiments, a bottom of the spacing structure 40 may be substantially coplanar with the top of the second well region 32 and may be substantially coplanar with the top of the first well region 31. In some embodiments, the spacing structure 40 is formed on the top region of the second well region 32, and the drain area 321 is exposed through the spacing structure 40, so one side of the spacing structure 40 may be substantially aligned with one side of the drain area 321 as shown in FIGS. 1 and 2. In some embodiments, a length L1 of the spacing structure 40 may range from about 0.1 μm to about 10 μm. In some embodiments, a length L1 of the spacing structure 40 may range from about 0.5 μm to about 8 μm. In some embodiments, a thickness T3 of the spacing structure 40 may range from about 10 nm to about 100 nm. In some embodiments, a ratio of the length L1 to the thickness T3 may range from about 100:1 to about 1:1. In some embodiments, a ratio of the length L1 to the thickness T3 may range from about 80:1 to about 2:1. In some embodiments, a ratio of the length L1 to the thickness T3 may range from about 50:1 to about 5:1.

A distance L2 between the spacing structure 40 and the first well region 31 may range from about 0.01 μm to about 1 μm, so that a distance between the drain area 321 and the first well region 31 may be at least a sum of the length L1 and the distance L2. In some embodiments, a ratio of the length L1 to the distance L2 may range from about 220:1 to about 5:1. In some embodiments, the ratio of the length L1 to the distance L2 may range from about 200:1 to about 10:1. In some embodiments, the ratio of the length L1 to the distance L2 may range from about 100:1 to about 20:1. In some embodiments, a distance L3 between the second well region 32 and the pair of oppositely doped regions 311 and 312 may range from about 0.01 μm to about 1 μm. A ratio of the length L1 to the distance L2 and the distance L3 may range from about 200:1:1 to about 30:3:1.

The gate structure 50 is partially formed on the well structure 30 and partially formed on the spacing structure 40. A source and a drain are formed on opposite sides of the gate structure 50, so that the pair of oppositely doped regions 311 and 312 and the drain area 321 are separately formed in the well structure 30. As shown in FIGS. 1 and 2, the gate structure 50 and the spacing structure 40 are formed on the well structure 30 between the pair of oppositely doped regions 311 and 312 and the drain area 321. The gate structure 50 comprises a gate dielectric layer 51, a gate electrode 52 and spacers 53. The gate dielectric layer 51 is formed on the well structure 30. In some embodiments, the gate dielectric layer 51 is partially formed on the first well region 31 and partially formed on the second well region 32. The gate dielectric layer 51 abuts the spacing structure 40. A bottom of the gate dielectric layer 51 may be substantially coplanar with the bottom of the spacing structure 40. In some embodiments, the gate dielectric layer 51 has a thickness T4, which is less than the thickness T4 of the spacing structure 40. In some embodiments, a ratio of the thickness T4 to the thickness T3 may range from about 1:10 to about 1:9. In some embodiments, the gate dielectric layer 51 may comprise a thickness less than about 10 nm.

The gate dielectric layer 51 may include a silicon dioxide (referred to as silicon oxide) layer suitable for high voltage applications. Alternatively, the gate dielectric layer 51 may optionally include a high-k dielectric material, silicon oxynitride, other suitable materials, or combinations thereof. The high-k material may be selected from metal oxides, metal nitrides, metal silicates, transition metal-oxides, transition metal-nitrides, transition metal-silicates, oxynitrides of metals, metal aluminates, zirconium silicate, zirconium aluminate, HfO₂, or combinations thereof. The gate dielectric layer 51 may have a multilayer structure, such as one layer of silicon oxide and another layer of high-k material. The gate dielectric layer 51 may be formed using chemical vapor deposition (CVD), physical vapor deposition (PVD), atomic layer deposition (ALD), thermal oxide, other suitable processes, or combinations thereof.

The gate electrode 52 may be configured to be coupled to metal interconnects and may be partially disposed overlying the gate dielectric layer 51 and partially disposed overlying the spacing structure 40 and thus include a first gate electrode 521 and a second gate electrode 522. The first gate electrode 521 is formed on the gate dielectric layer 51 and the second gate electrode 522 is formed on the spacing structure 40. A top of the first gate electrode 521 is substantially coplanar with a top of the second gate electrode 522. The first gate electrode 521 comprises a thickness T5, which may be greater than a thickness T6 of the second gate electrode 522. In some embodiments, the thickness T5 of the first gate electrode 521 may range from about 30 nm to about 300 nm. In some embodiments, a ratio of the thickness T5 to the thickness T6 may range from about 10:9 to about 10:1. In some embodiments, the ratio of the thickness T5 to the thickness T6 may range from about 5:4 to about 5:1. In some embodiments, a length L5 of the first gate electrode 521 is equal to or greater than a length L6 of the second gate electrode 522. In some embodiments, a ratio of the length L5 to the length L6 may be from about 20:19 to about 20:1. In some embodiments, the ratio of the length L5 to the length L6 may be from about 10:9 to about 10:1.

The gate electrode 52 may include a doped or non-doped polycrystalline silicon (or polysilicon). Alternatively, the gate electrode 52 may include a metal, such as Al, Cu, W, Ti, Ta, TiN, TaN, NiSi, CoSi, other suitable conductive materials, or combinations thereof. The gate electrode 52 may be formed by CVD, PVD, ALD, plating, and other proper processes. The gate electrode may have a multilayer structure and may be formed in a multiple-step process. Gate terminal 54 is electrically connected to the gate electrode 52 as shown in FIG. 2.

One of the spacers 53 is formed on the well structure 30 and the other of the spacers 53 is formed on the spacing structure 40 so the gate electrode 52 is sandwiched by the spacers 53 and the gate dielectric layer 51 is sandwiched by one of the spacers 53 and the spacing structure 40. The spacers 53 include materials such as silicon oxide (SiOₓ), silicon nitride (SiNₓ), silicon oxynitride, carbon doped silicon oxide, carbon doped silicon nitride, carbon doped silicon oxynitride, zinc oxide, zirconium oxide, hafnium oxide or titanium oxide. A thickness of the spacers 53 may range from about 50 nanometers to about 500 nanometers.

Referring to FIG. 2, the semiconductor structure further comprises a metal field plate (MFP) 60 electrically connecting the gate terminal 54. The metal field plate 60 may comprise conductive materials, such as metals, including but not limited to Cu, Al and so on. The metal field plate 60 is located above the spacing structure 40 and apart from the drain area 321 with a distance D1, and apart from the pair of oppositely doped regions 311 and 312 with a distance D2, so that the metal field plate 60 can be apart from the drain area 321 (i.e., the source area) to keep a high breakdown voltage (BV); for example, higher than 50V. In some embodiments, the length L7 of the metal field plate 60 may range from about 0.5 μm to about 5 μm. In some embodiments, a ratio of the length L7 to the length L1 may range from about 1:1 to about 1:20. In some embodiments, the ratio of the length L7 to the length L1 may range from about 19:20 to about 1:10. In some embodiments, the ratio of the length L7 to the length L1 may range from about 9:10 to about 1:5. In some embodiments, the ratio of the length L7 to the length L1 may range from about 3:5 to about 1:5. The metal field plate 60 has a thickness T7, which may range from about 30 nm to about 300 nm. In some embodiments, a ratio of the thickness T7 to the length L7 may range from about 1:250 to about 1:2. In some embodiments, a ratio of the thickness T7 to the length L7 may range from about 1:100 to about 1:10. In some embodiments, a ratio of the thickness T7 to the thickness T3 of the spacing structure 40 may range from about 30:1 to about 1:30. In some embodiments, a ratio of the thickness T7 to the thickness T3 of the spacing structure 40 may range from about 20:1 to about 1:10. In some embodiments, a ratio of the thickness T7 to the thickness T3 of the spacing structure 40 may range from about 15:1 to about 1:1. The distance D1 may range from about 0.2 μm to about 2 μm. In some embodiments, a ratio of the distance D1 to the length L7 may range from about 1:30 to about 1:1. In some embodiments, a ratio of the distance D1 to the length L7 may range from about 1:20 to about 1:3. The distance D2 may range from about 0.09 μm to about 3 μm. In some embodiments, a ratio of the distance D2 to the length L7 may range from about 1:50 to about 1:5. In some embodiments, a ratio of the distance D2 to the length L7 may range from about 1:30 to about 1:10.

A distance T8 between the metal field plate 60 and the gate electrode 52 may range from about 30 nm to about 300 nm. In some embodiments, a ratio of the distance T8 to the thickness T7 of the metal field plate 60 may range from about 1:10 to about 10:1. In some embodiments, a ratio of the distance T8 to the thickness T7 of the metal field plate 60 may range from about 1:5 to about 5:1. In some embodiments, the distance T8 may be substantially identical to the thickness T7.

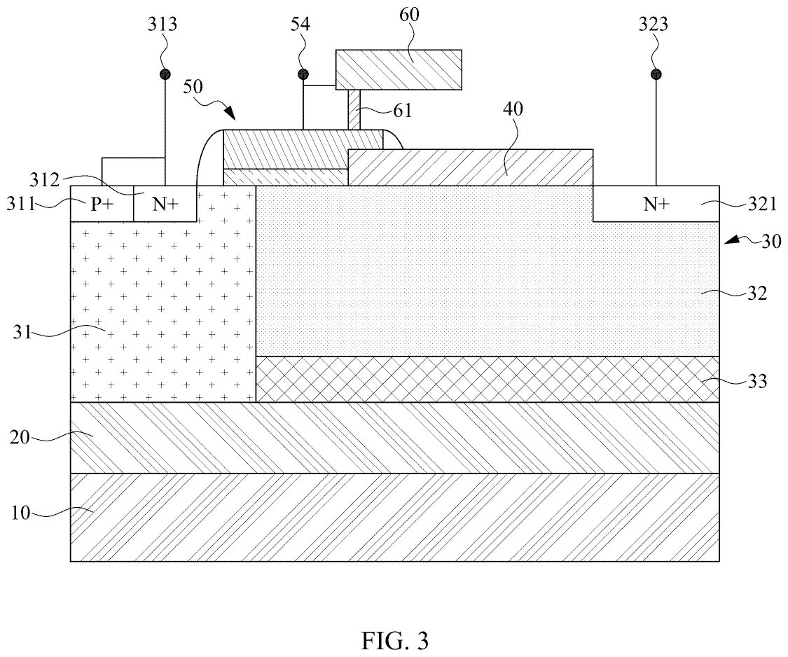

In some embodiments as shown in FIG. 3, the metal field plate 60 may be connected to the gate electrode 52 through a contacting line 61, which may be made of metals. The contacting line 61 may comprises a length equal to the distance T8 between the metal field plate 60 and the gate electrode 52.

As shown in FIG. 2, the metal field plate 60 is located above the spacing structure 40 and has one side substantially aligned with one side of the gate electrode 52 located on the spacing structure 40. As shown in FIG. 3, the metal field plate 60 is located above the spacing structure 40 and partially above the gate electrode 52. The metal field plate 60 has one side substantially aligned with one side of the spacing structure 40 abutting the first gate electrode 521.

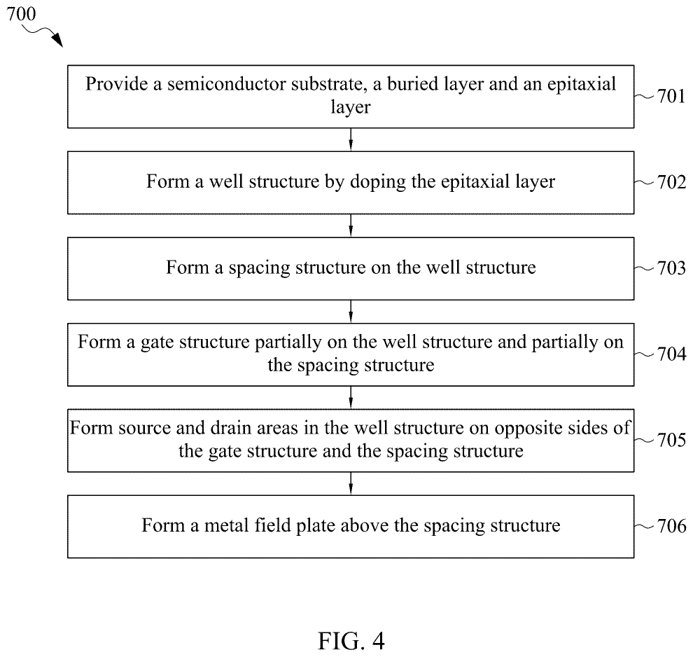

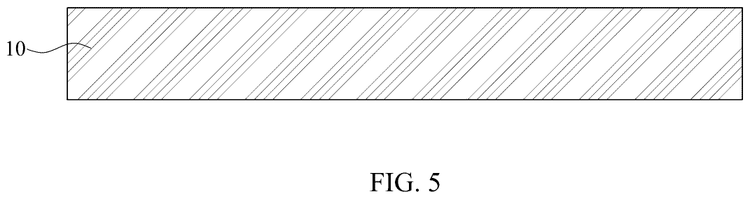

FIG. 4 is a flowchart representing a method 700 for forming a semiconductor structure according to various aspects of the present disclosure. In some embodiments, the method 700 for forming the semiconductor structure includes a number of operations (701, 702, 703, 704, 705 and 706). The method 700 for forming the semiconductor structure will be further described according to one or more embodiments. It should be noted that the operations of the method 700 may be rearranged or otherwise modified within the scope of the various aspects. It should further be noted that additional processes may be provided before, during, and after the method 700, and that some other processes may be only briefly described herein. FIGS. 5 to 16 are diagrammatic perspective views illustrating various stages in the method 700 for forming the semiconductor structure according to aspects of one or more embodiments of the present disclosure.

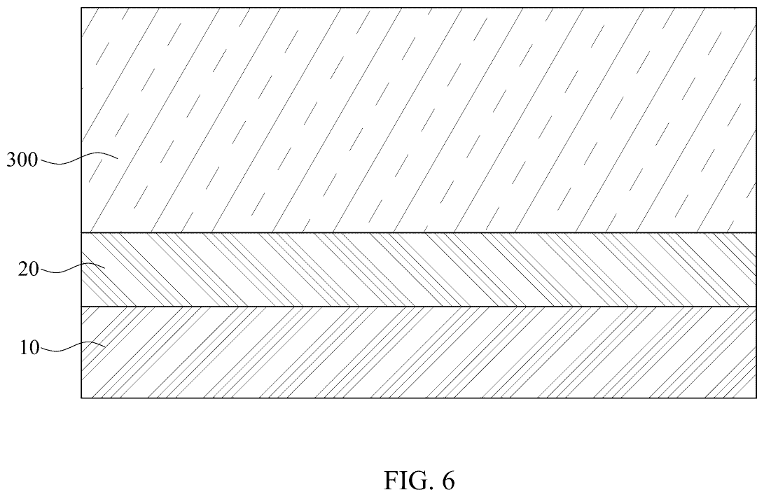

With reference to FIGS. 5 and 6, the method 700 begins at operation 701 where a semiconductor substrate 10, a buried layer 20 and an epitaxial layer 300 are provided. The semiconductor substrate 10 has a first type of conductivity. For example, the semiconductor substrate 10 may be p-type. The buried layer 20 is formed on the semiconductor substrate 10. The buried layer 20 may be an n-type buried layer (NBL), a p-type buried layer (PBL), and/or a buried dielectric layer including a buried oxide (BOX) layer. In some embodiment, the buried layer 20 may comprise n-type dopants (e.g., N+ dopants) including phosphorus, arsenic, other n-type dopant, or combinations thereof on a P-type semiconductor substrate 10. The epitaxial layer 300 is formed over the buried layer 20, which may comprise silicon.

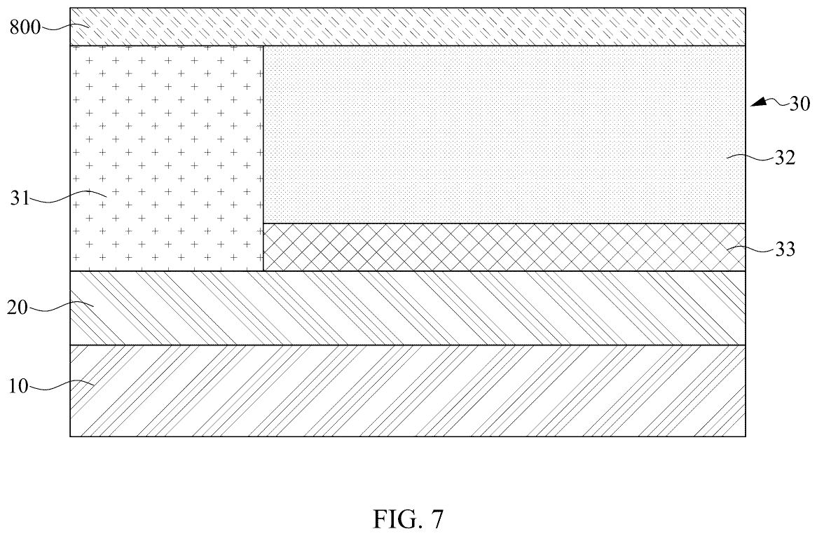

The method 700 continues at operation 702 as shown in FIG. 7 in which a well structure 30 is formed by implanting the epitaxial layer 300. In some embodiments, before implantation, a sacrificial layer 800 may be formed over the epitaxial layer 300 to protect the epitaxial layer 300 during implantation. The sacrificial layer 800 may have a thickness, which is substantially identical to a thickness of the spacing structure 40 to be formed. A first selected area of the epitaxial layer 300 is implanted with dopants with a first conductivity type to form a first well region 31 and a second selected area of the epitaxial layer 300 adjacent to the first selected area is implanted with dopants with a second conductivity type to form a second well region 32. A third selected area of the epitaxial layer 300 adjacent to the first selected area and underneath the second selected area can be implanted with dopants with a first conductivity type to form a third well region 33. In some embodiments, the implantation of the third selected area of the epitaxial layer 300 may be performed before the implantation of the second selected area of the epitaxial layer 300. In some embodiments, the implantation of the third selected area of the epitaxial layer 300 may be performed before, during or after the implantation of the first area of the epitaxial layer 300.

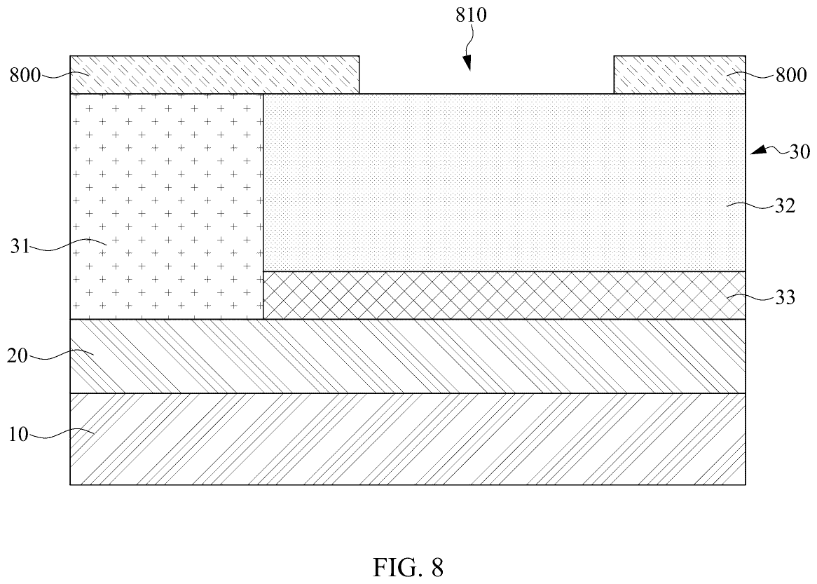

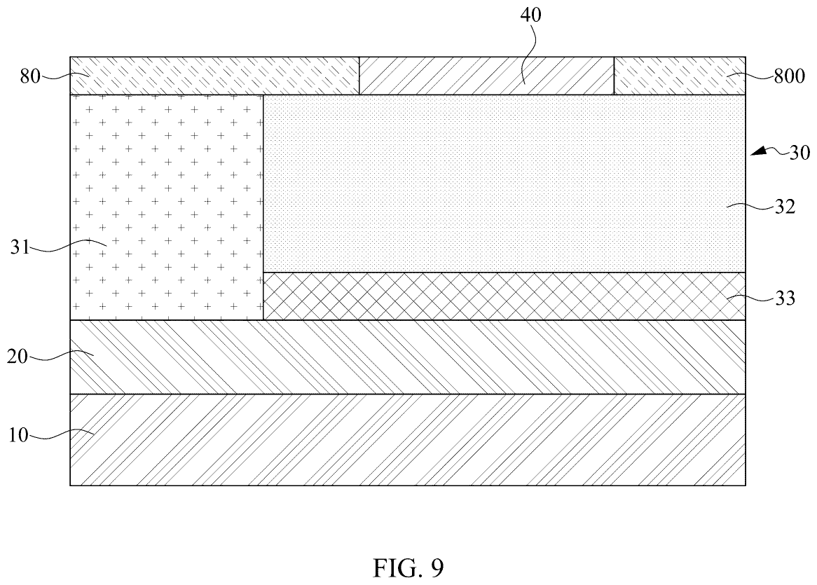

At operation 703, a spacing structure 40 is formed on the well structure 30 by etching the sacrificial layer 800 to form a recess 810 so as to identify the location of the spacing structure 40 to be formed as shown in FIG. 8; and forming a spacing structure 40 in the recess 810 as shown in FIG. 9 by depositing an insulating material. In some embodiments, the insulating material may include oxide, such as silicon oxide, metal oxide or any other oxide materials. After forming the spacing structure 40, the sacrificial layer 800 can be removed. A planarization process may be performed to remove superfluous insulating material so that the thickness of the spacing structure 40 can be substantially identical to the thickness of the sacrificial layer 800.

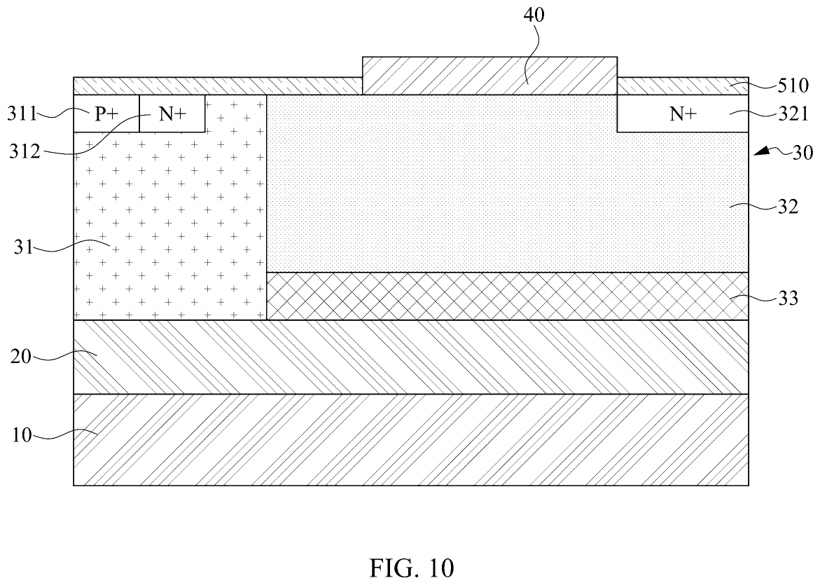

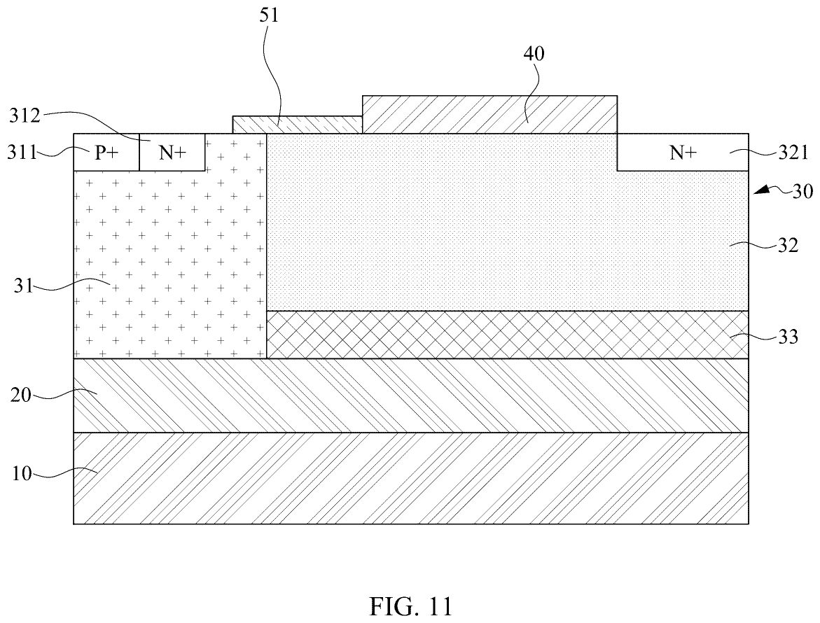

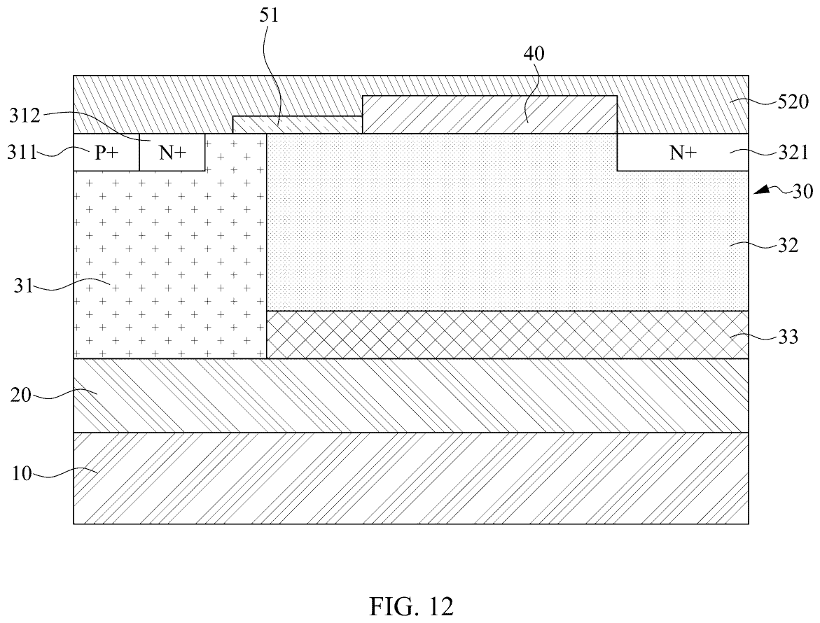

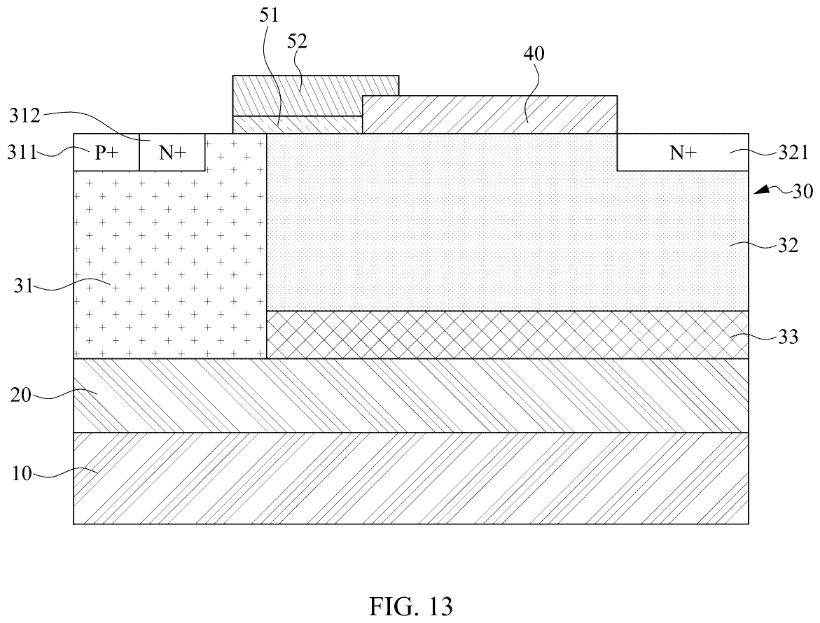

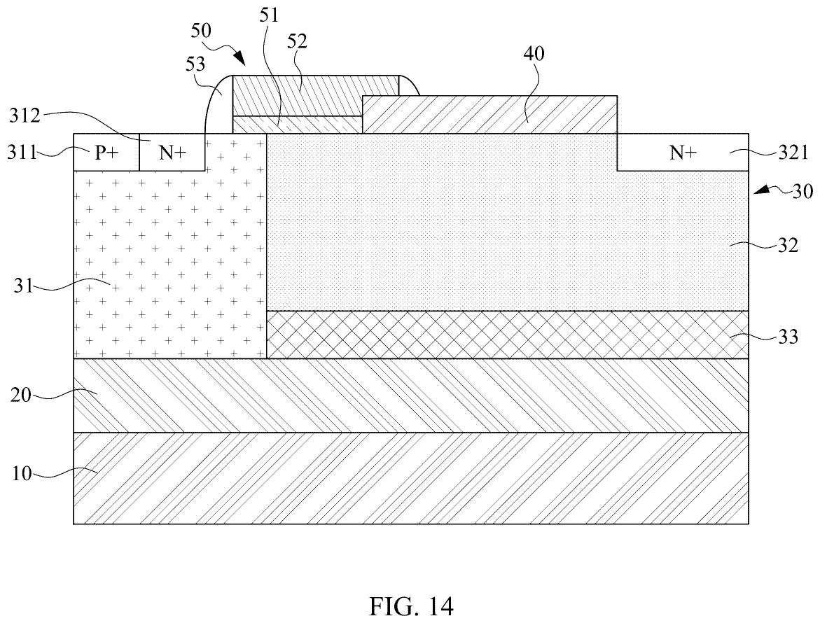

As shown in FIG. 10, the method 700 then proceeds to operation 704 where a gate structure 50 is formed partially on the well structure 30 and partially on the spacing structure 40. The gate structure 50 is formed by forming a dielectric material 510 over the well structure 30 with the thickness less than a thickness of the spacing structure 40 as shown in FIG. 10; forming a gate dielectric layer 51 by patterning the dielectric material 510 so that the gate dielectric layer 51 abuts the spacing structure 40 as shown in FIG. 11; depositing a conductive material 520 onto the well structure 30, the gate dielectric layer 51 and the spacing structure 40 with a thickness greater than the thickness of the spacing structure 40 as shown in FIG. 12; forming a gate electrode 52 by patterning the conductive material 520 so that the gate electrode 52 is formed on the gate dielectric layer 51 and on a portion of the spacing structure 40 as shown in FIG. 13; and forming spacers 53 respectively on the well structure 30 and the spacing structure 40 so the gate electrode 52 is sandwiched by the spacers 53 and the gate dielectric layer 51 is sandwiched by one of the spacers 53 and the spacing structure 40 as shown in FIG. 14. In some embodiments, the conductive material 520 may be conformally deposited onto the well structure 30, the gate dielectric layer 51 and the spacing structure 40. Therefore, a thickness of a layer formed of the conductive material 520 may be substantially uniform. Then, a planarization procedure, such as a chemical-mechanical planarization (CMP), may be performed to planarize a top of the conductive material 520, so that the layer formed of the conductive material 520 may have non-even thicknesses and a top of the gate electrode 52 can be substantially flat. The gate dielectric layer 51 is partially formed on the first well region 31 and partially on the second well region 32.

Also referring to FIG. 10, at operation 705, source and drain areas are formed in the well structure 30 on opposite sides of the gate structure 50 and the spacing structure 40. Forming a source area comprises forming a pair of oppositely doped regions 311 and 312 in a top region of the first well region 31, which is not overlaid by the gate structure 50, by implanting the top region of the first well region 31 with dopants with a first conductivity type and dopants with a second conductivity type so as to form a first doped region 311 comprising dopants with the first conductivity type and a second doped region 312 comprising dopants with the second conductivity type. Forming a drain area comprises implanting a top region of the second well region 32, which is not overlaid by the spacing structure 40, with dopants with a first conductivity type to form a drain area 321.

After forming the gate structure 50, an interlayer dielectric (ILD) layer 900 can be formed on the well structure 30, the spacing structure 40 and the gate structure 50. The ILD layer 900 is made of, for example, one or more layers of low-k dielectric material. Low-k dielectric materials have a k-value (dielectric constant) lower than about 4.0. Some low-k dielectric materials have a k-value lower than about 3.5 and other low-k dielectric material may have a k-value lower than about 2.5. Material for forming the ILD layer 900 includes compounds comprising elements of Si, O, C and/or H, such as SiCOH and SiOC. Organic materials, such as polymers, may be used for the ILD layer 900. For example, the ILD layer 900 is made of one or more layers of a carbon-containing material, organo-silicate glass, a porogen-containing material, and/or combinations thereof. Nitrogen may also be included in the ILD layer 900 in some embodiments. The ILD layer 900 may be a porous layer. The density of the ILD layer 900 is less than about 3 g/cm³ in one embodiment and may be less than about 2.5 g/cm³ in other embodiments. The ILD layer 900 may be formed by using, for example, plasma-enhanced chemical vapor deposition (PECVD), low pressure CVD (LPCVD), atomic layer CVD (ALCVD), and/or a spin-on technology. In case of PECVD, the film is deposited at a substrate temperature in a range of about 25° C. to about 400° C. and at a pressure of less than 100 Torr.

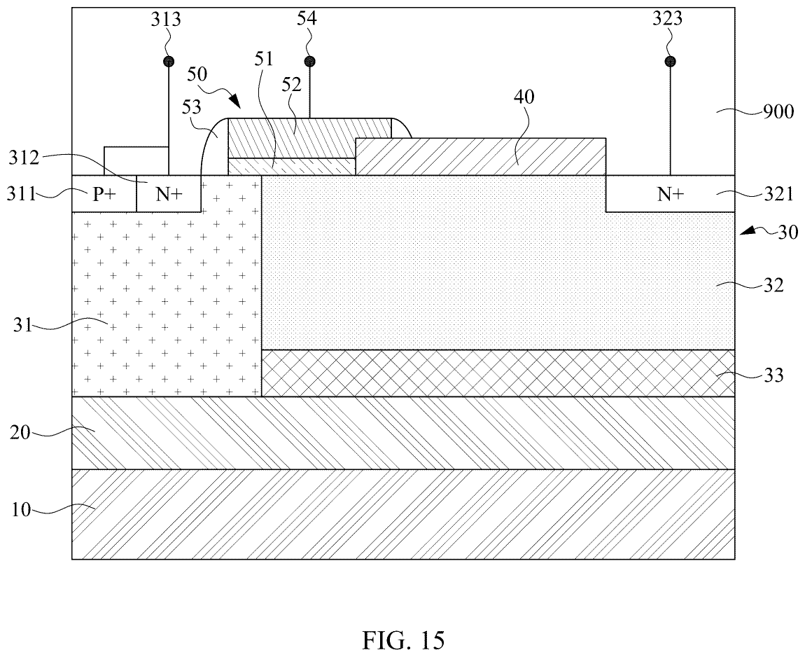

As shown in FIG. 15, further processing can be performed including forming a source terminal 313, a drain terminal 323 and a gate terminal 54 in the ILD layer 900; and electrically connecting the pair of oppositely doped regions 311 and 312 to a source terminal 313, electrically connecting the drain area 321 to a drain terminal 323, and electrically connecting the gate electrode 52 to a gate terminal 54.

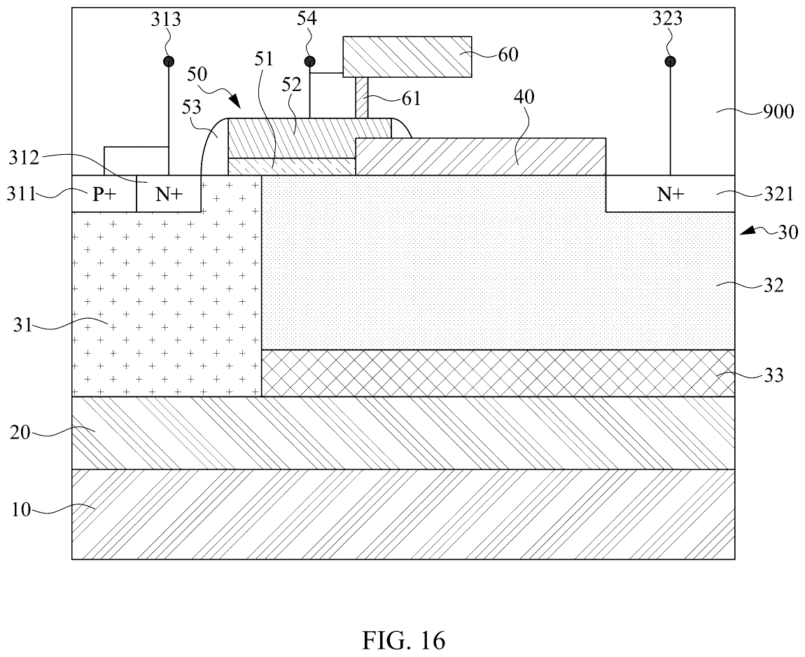

At operation 705, a metal field plate 60 is formed in the ILD layer 900 and above the spacing structure 40. The metal field plate 60 electrically connects the gate terminal 54. As shown in FIG. 16, the metal field plate 60 connects to the gate electrode 52 through a contacting line 61. The metal field plate 60 is made of metal, such as Al, Cu and so on. In some embodiments, the metal field plate 60 may be formed before, during or after forming the source terminal 313, the drain terminal 323 and/or the gate terminal 54.

Due to the formation of the spacing structure 40 and the metal filed plate 60 and their dimension and relative locations, performance of the semiconductor structure (such as, a MOS transistor) can be improved. Both of the on-state resistance (Ron) and the total gate charge (Qg) can be reduced. The on-state resistance (Ron) can be less than 20 mΩ-mm². The total gate charge (Qg) can be less than 5 nC/mm². Thus, the total gate charge (Ron×Qg) can be reduced, which can be less than 100 mΩ-nC. The spacing structure 40 can be used to reduce a surface electric field. The formation of the metal filed plate 60 is essential for maintaining the breakdown voltage (BV) greater than 50V, on-state breakdown voltage (BVₒₙ) equal to or greater than 50V and off-state current (Ioff) lower than 1 pA/μm.

In some embodiments, a method for forming a semiconductor structure of the present invention comprises providing a semiconductor substrate with a buried layer and an epitaxial layer formed on the semiconductor substrate; implanting a first selected area of the epitaxial layer with dopants with a first conductivity type to form a first well region and implanting a second selected area of the epitaxial layer with dopants with a second conductivity type to form a second well region, wherein the first well region and the second well region are adjacent to each other; forming a spacing structure on the second well region, wherein the spacing structure comprises an insulating material; forming a gate structure partially on the first well region and the second well region and partially on the spacing structure; and forming a metal field plate above the spacing structure, wherein the metal field plate electrically connects the gate structure and comprises a conductive material, wherein a bottom of the spacing structure is substantially coplanar with a top of the first well region and a top of the second well region.

In some embodiments, a method for forming a semiconductor structure of the present invention comprises providing a semiconductor substrate with an epitaxial layer overlying the semiconductor substrate; implanting a first selected area of the epitaxial layer with dopants with a first conductivity type to form a first well region and implanting a second selected area of the epitaxial layer with dopants with a second conductivity type to form a second well region, wherein the first well region and the second well region are adjacent to each other; forming a spacing structure on the second well region, wherein the spacing structure comprises an insulating material; forming a gate structure partially on the first well region and the second well region and partially on the spacing structure; and forming a source area in a top region of the first well region exposed from the gate structure and forming a drain area in a top region of the second well region exposed from the spacing structure wherein a bottom of the spacing structure is substantially coplanar with a top of the first well region and a top of the second well region.

In some embodiments, a semiconductor structure of the present invention comprises a well structure formed on a semiconductor substrate comprises a first well region of a first conductivity type and a second well region of a second conductivity type opposite to the first conductivity type; a spacing structure formed on the second well region and comprising an insulating material; a gate structure partially formed on the well region and partially formed on the spacing structure; and a metal field plate formed above the spacing structure and connecting the gate structure, wherein the metal field plate comprises a conductive material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for manufacturing a semiconductor structure, comprising:
providing a semiconductor substrate with a buried layer and an epitaxial layer formed on the semiconductor substrate;
implanting a first selected area of the epitaxial layer with dopants with a first conductivity type to form a first well region and implanting a second selected area of the epitaxial layer with dopants with a second conductivity type to form a second well region, wherein the first well region and the second well region are adjacent to each other;
forming a spacing structure on the second well region, wherein the spacing structure comprises an insulating material;
forming a gate structure partially on the first well region and the second well region and partially on the spacing structure; and
forming a metal field plate above the spacing structure, wherein the metal field plate electrically connects the gate structure and comprises a conductive material,
wherein a bottom of the spacing structure is substantially coplanar with a top of the first well region and a top of the second well region.

2. The method of claim 1, further comprising:
forming an interlayer dielectric (ILD) layer on the first well region, the second well region, the spacing structure and the gate structure after forming the gate structure; and
forming a source terminal connecting to the first well region, a drain terminal and a gate terminal in the ILD layer,
wherein the metal field plate is formed in the ILD layer, and
wherein a ratio of a distance between the metal field plate and the gate structure to a thickness of the metal field plate ranges from about 1:10 to about 10:1.

3. The method of claim 2, wherein the metal field plate electrically connects the gate terminal.

4. The method of claim 1, wherein forming the gate structure comprises:
forming a gate dielectric layer on the first well region and the second well region and abutting the spacing structure;
forming a gate electrode on the gate dielectric layer and on a portion of the spacing structure; and
forming spacers respectively on the first well region and the spacing structure so the gate dielectric layer is sandwiched by one of the spacers and the spacing structure, and the gate electrode is sandwiched by the spacers, and
wherein the metal field plate has one side substantially aligned with one side of the gate electrode located on the spacing structure.

5. The method of claim 1, wherein the metal field plate has one side substantially aligned with one side of the spacing structure abutting the gate structure.

6. The method of claim 1, wherein a ratio of a distance between the metal field plate and one side of the spacing structure away from the first well region to a length of the metal field plate ranges from about 1:30 to about 1:1.

7. The method of claim 1, further comprising, before forming the spacing structure, implanting a third selected area of the epitaxial layer adjacent to the first selected area and underneath the second selected area with dopants complementary to the dopants in the second well region to form a third well region.

8. A method for manufacturing a semiconductor structure, comprising:
providing a semiconductor substrate with an epitaxial layer overlying the semiconductor substrate;
implanting a first selected area of the epitaxial layer with dopants with a first conductivity type to form a first well region and implanting a second selected area of the epitaxial layer with dopants with a second conductivity type to form a second well region, wherein the first well region and the second well region are adjacent to each other;
forming a spacing structure on the second well region, wherein the spacing structure comprises an insulating material;
forming a gate structure partially on the first well region and the second well region and partially on the spacing structure; and
forming a source area in a top region of the first well region exposed from the gate structure and forming a drain area in a top region of the second well region exposed from the spacing structure wherein a bottom of the spacing structure is substantially coplanar with a top of the first well region and a top of the second well region.

9. The method of claim 8, wherein forming the source area and the drain area comprises:
implanting the top region of the first well region exposed from the gate structure with dopants with the first conductivity type and dopants with the second conductivity type to form a pair of oppositely doped regions as the source area including a first doped region comprising dopants with the first conductivity type and a second doped region comprising dopants with the second conductivity type; and
implanting the top region of the second well region exposed from the spacing structure with dopants with the first conductivity type to form the drain area.

10. The method of claim 9, further comprising
forming a source terminal electrically connecting the pair of oppositely doped regions;
forming a drain terminal electrically connecting the drain area; and
forming a gate terminal electrically connecting the gate electrode and the metal field plate.

11. The method of claim 8, wherein forming the gate structure comprises:
forming a gate dielectric layer on the first well region and the second well region and abutting the spacing structure;
forming a first gate electrode on the gate dielectric layer and forming a second gate electrode on a portion of the spacing structure; and
forming a first spacer on the first well region abutting a sidewall of the first gate electrode and forming a second spacer on the spacing structure abutting a sidewall of the second gate electrode.

12. The method of claim 11, wherein a top of the first gate electrode is substantially coplanar with a top of the second gate electrode; and a thickness of the first gate electrode to a thickness of the second gate electrode ranges from about 10:9 to about 10:1.

13. The method of claim 8, wherein a ratio of a length of the spacing structure to a thickness of the spacing structure ranges from about 100:1 to about 1:1.

14. A semiconductor structure, comprising:
a well structure formed on a semiconductor substrate and comprising a first well region of a first conductivity type and a second well region of a second conductivity type opposite to the first conductivity type;
a spacing structure formed on the second well region and comprising an insulating material;
a gate structure partially formed on the well region and partially formed on the spacing structure; and
a metal field plate formed above the spacing structure and connecting the gate structure, wherein the metal field plate comprises a conductive material.

15. The semiconductor structure of claim 14, wherein a top of the first well region and a top of the second well region are substantially coplanar with each other, so a bottom of the spacing structure is substantially coplanar with the top of the first well region and the top of the second well region.

16. The semiconductor structure of claim 14,
wherein the first well region is a p-type region and comprises a pair of oppositely doped regions in a top region of the first well region exposed from the gate structure, which include a first doped region comprising dopants with a first conductivity type and a second doped region comprising dopants with a second conductivity type,
wherein the second well region is an n-type region and comprises a drain area formed in a top region of the second well region exposed from the spacing structure, and
wherein the gate structure and the spacing structure are formed on the well structure between the pair of oppositely doped regions and the drain area.

17. The semiconductor structure of claim 16, further comprises:
a source terminal electrically connecting the pair of oppositely doped regions;
a drain terminal electrically connecting the drain area; and
a gate terminal electrically connecting the gate electrode and the metal field plate.

18. The semiconductor structure of claim 14, wherein the gate structure comprises:
a gate dielectric layer formed on the well structure and abutting the spacing structure;
a gate electrode comprising a first gate electrode formed on the gate dielectric layer and a second gate electrode formed on the spacing structure; and
a first spacer formed on the first well region abutting the gate dielectric layer and the gate electrode; and
a second spacer formed on the spacing structure abutting the gate electrode, so that the gate dielectric layer is sandwiched by one of the first spacer and the spacing structure, and the gate electrode is sandwiched by the first spacer and the second spacer.

19. The semiconductor structure of claim 18, wherein a top of the first gate electrode is substantially coplanar with a top of the second gate electrode; and wherein a thickness of the first gate electrode to a thickness of the second gate electrode ranges from about 10:9 to about 10:1.

20. The semiconductor structure of claim 14, wherein a length of the metal field plate is equal to or less than a length of the spacing structure.
